(19) United States
(12) Patent Application Publication
(10) Pub. No.: US 2018/0166117 A1
(43) Pub. Date: Jun. 14, 2018

(54) MEMROY DEVICE AND OPERATING METHOD THEREOF

(71) Applicant: SK hynix Inc., Gyeonggi-do (KR)

(72) Inventors: Hae-Rang CHOI, Gyeonggi-do (KR); Youk-Hee KIM, Gyeonggi-do (KR); Jae-Seung LEE, Gyeonggi-do (KR); Mi-Hyeon JO, Gyeonggi-do (KR); Dong-Jae LEE, Gyeonggi-do (KR); Kyeong-Pil KANG, Gyeonggi-do (KR); Sung-Soo CHI, Gyeonggi-do (KR); Hyung-Sik WON, Chungcheongbuk-do (KR); Hun-Sam JUNG, Gyeonggi-do (KR); Yo-Sep LEE, Gyeonggi-do (KR)

(21) Appl. No.: 15/681,595

(22) Filed: Aug. 21, 2017

(30) Foreign Application Priority Data
Dec. 14, 2016 (KR) 10-2016-0170437

(51) Int. Cl. G11C 11/404; G11C 11/406

(52) U.S. Cl. CPC G11C 11/4045; G11C 2211/4068; G11C 11/40626; G11C 11/40622

(57) ABSTRACT

An operating method of a memory device including a plurality of memory cells may include: measuring data retention times of at least a portion of the plurality of memory cells; and optimizing a refresh operation on the plurality of memory cells using the measurement result.

### CROSS-REFERENCE TO RELATED APPLICATIONS

The present application claims priority of Korean Patent Application No. 10-2016-0170437, filed on Dec. 14, 2016, which is incorporated herein by reference in its entirety.

### BACKGROUND

### 1. Field

This patent document relates to a semiconductor memory device and an operating method thereof.

### 2. Description of the Related Art

In general, a memory cell of a semiconductor memory device such as a Dynamic Random Access Memory (DRAM) includes a transistor serving as a switch and a capacitor for storing a charge (data). Depending on whether the capacitor of the memory cell is charged or not, that is, whether a voltage across the capacitor is high or low, a logic level of data is determined as a logic high level, or a logic low level.

Since data are stored in such a manner that charges are accumulated in the capacitor, no power is consumed in principle for maintaining the stored data. However, due to a leakage current due to the PN junction of a MOS transistor, the initial charge stored in the capacitor may after some time disappear resulting in the loss of the data. In order to prevent such data losses, stored data are read before they are lost, and the memory cells are recharged according to the read data. Such an operation is periodically repeated to retain the data. The operation of recharging the memory cell is referred to as a refresh operation.

Typically, the refresh operation is performed whenever a refresh command is inputted to a memory from a memory controller. Considering the data retention time of the memory, the memory controller inputs the refresh command to the memory at each predetermined time. For example, when the data retention time of the memory is 64 ms and the whole memory cells of the memory can be refreshed only in the case where the refresh command is inputted 8,000 times, the memory controller must input 8,000 refresh commands to the memory device during the 64 ms.

When the data retention times of some memory cells included in a memory device do not reach a minimum reference retention time during a test process of the memory device, the memory device is discarded as a failed memory device.

When all memory devices including any memory cell (hereinafter, referred to as a “weak cell”) of which the data retention times do not reach the minimum reference retention time are discarded, the yield inevitably decreases. Furthermore, even a memory device which passed a data retention test may still cause an error when a weak cell occurs due to a posterior cause during the repeated use of the device.

According to recent developments in semiconductor integration technology, tens of millions of memory cells can be integrated in a single chip. As a result, despite improvements in the fabrication processes of semiconductor memory devices, the possibility that a weak cell will occur has increased. Unless an accurate test for such a weak cell is performed, the reliability of the semiconductor memory device cannot be assured. Therefore, research is being conducted on a variety of schemes and methods for detecting weak cells and a variety of techniques for managing weak cells.

### SUMMARY

Various embodiments of the present invention are directed to an improved memory device comprising a plurality of memory cells which can reduce the current and power consumption of a refresh operation while preventing a deterioration in data of weak cells. Various embodiments of the present invention are also directed to an operating method of the memory device.

The memory device can measure a data retention time of one or more memory cells, and optimize a refresh operation for the plurality of memory cells according to the measurements, thereby minimizing current and power consumption of the refresh operation while preventing a deterioration in data of weak cells.

In an embodiment, an operating method of a memory device including a plurality of memory cells may include: measuring data retention times of at least a portion of the plurality of memory cells; and optimizing a refresh operation on the plurality of memory cells using the measurement result.

The operating method may further include: storing the measurement result of the data retention times of the plurality of memory cells.

The measuring of the data retention times may include: writing test data to the plurality of memory cells; skipping a refresh operation on one or more test cells among the plurality of memory cells by a preset number of times; and detecting the data retention times of the test cells by comparing the test data to data of the test cells.

The measuring of the data retention times may include: a first detection step of detecting a cell group of which the data retention time is less than a reference time, among two or more cell groups, wherein the cell group comprises memory cells included in two or more rows, among the plurality of memory cells; and a second detection step of detecting a sub cell group of which the data retention time is less than the reference time, among two or more sub cell groups included in the cell group detected at the first detection step, wherein the sub cell group comprises memory cells included in one or more rows of the two or more rows included in the cell group detected at the first detection step.

The storing of the measurement result may include: storing the measurement result in a nonvolatile memory, a plurality of dummy cells, a plurality of latches or a plurality of fuses.

The optimizing of the refresh operation may include: reading the measurement result stored in the nonvolatile memory, the plurality of dummy cells or the plurality of latches; and adjusting a refresh cycle of the memory cell according to the measurement result.

The optimizing of the refresh operation may include: detecting one or more weak cells having a shorter data retention time than a reference time, based on the measurement result, among the plurality of memory cells; optimizing the refresh operation by increasing the data retention time of the weak cells or correcting data of the weak cells, and increasing a refresh cycle of the weak cell.

The optimizing of the refresh operation may include: detecting one or more weak cells having a shorter data retention time than a first reference time, and detecting one or more strong cells having a longer data retention time than a second reference time, based on the measurement result, among the plurality of memory cells; and minimizing a refresh frequency by decreasing a refresh cycle of the weak cells and increasing a refresh cycle of the strong cells.

The measurement result may include an address of a weak cell or one-bit data indicating whether each memory cell is a weak cell.

In an embodiment, a memory device may include: a plurality of memory cells; a test control unit suitable for measuring data retention times of the plurality of memory cells; and a refresh control unit suitable for controlling a refresh operation on the plurality of memory cells to be optimized, using the measurement result of the test control unit.

The test control unit may write test data to the plurality of memory cells, skips a refresh operation on one or more test cells among the plurality of memory cells by a preset number of times, and detect the data retention times of the test cells by comparing the test data and data of the test cells.

The test control unit may detect a cell group of which the data retention time is less than a reference time, among two or more cell groups, and detect a sub cell group of which the data retention time is less that the reference time, among two or more sub cell groups included in the detected cell group, wherein the cell group may include memory cells included in two or more rows among the plurality of memory cells and the sub cell group comprises memory cells included in one or more rows of two or more rows included in the cell group.

The memory device may further include a result storage unit suitable for storing the measurement result of the test control unit.

The result storage unit may include a nonvolatile memory, a plurality of dummy cells, a plurality of latches or a plurality of fuses.

The refresh control unit may adjust a refresh cycle of the memory cell by referring to the measurement result stored in the result storage unit.

The refresh control unit may detect one or more weak cells having a shorter data retention time than a reference time, based on the measurement result, among the plurality of memory cells, and optimize the refresh operation by increasing the data retention time of the weak cells or correcting data of the weak cells, and increasing a refresh cycle of the weak cell.

The refresh control unit may detect one or more weak cells having a shorter data retention time than a first reference time, and detect one or more strong cells having a longer data retention time than a second reference time, based on the measurement result, among the plurality of memory cells, and optimize the refresh operation by decreasing a refresh cycle of the weak cells and increasing a refresh cycle of the strong cells.

The memory device may further include: a temperature measurement unit suitable for measuring a temperature at which the plurality of memory cells operate.

The refresh control unit may increase a refresh frequency as the temperature measured by the temperature measurement unit rises, and decrease the refresh frequency as the temperature measured by the temperature measurement unit falls.

The measurement result may include an address of a weak cell or one-bit data indicating whether each memory cell is a weak cell.

### BRIEF DESCRIPTION OF THE DRAWINGS

FIG. 1 is a block diagram illustrating a memory device in accordance with an embodiment of the present invention.

FIG. 2 is a flowchart of an operating method of a memory device in accordance with an embodiment of the present invention.

FIG. 3 is a flowchart of a test operation method in accordance with an embodiment of the present invention.

FIG. 4 is a diagram describing a test operation method in accordance with a first embodiment of the present invention.

FIG. 5 is a diagram describing a test operation method in accordance with a second embodiment of the present invention.

FIG. 6A is a diagram illustrating a state in which a plurality of memory cells are electrically coupled to one bit line at the same time.

FIG. 6B is a graph illustrating how a voltage of the bit line is changed with time, depending on data retention times of the memory cells of FIG. 6A.

FIG. 7 is a diagram describing a test operation method in accordance with a third embodiment of the present invention.

FIG. 8 is a block diagram describing a method for storing a measurement result in accordance with an embodiment of the present invention.

FIG. 9 is a block diagram describing a method for storing the measurement result in accordance with an embodiment of the present invention.

FIG. 10 is a diagram describing an operation of transmitting result information stored in a nonvolatile memory to a dummy cell region.

FIG. 11 is a diagram describing an operation of transmitting result information stored in the dummy cell region to a refresh control unit during a refresh operation.

FIG. 12 is a diagram describing a general refresh operation.

FIG. 13 is a diagram describing a method for adjusting a refresh frequency or cycle of the refresh control unit in accordance with an embodiment of the present invention.

FIG. 14 is a diagram describing a method for adjusting a refresh frequency or cycle of the refresh control unit in accordance with an embodiment of the present invention.

FIG. 15 is a diagram describing a method for adjusting a refresh frequency or cycle of the refresh control unit in accordance with an embodiment of the present invention.

FIG. 16 is a diagram describing a method for adjusting a refresh frequency or cycle by correcting data of weak cells.

### DETAILED DESCRIPTION

Various embodiments of the present invention will be described below in more detail with reference to the accompanying drawings. These embodiments are provided so that this disclosure is thorough and complete. All “embodiments” referred to in this disclosure refer to embodiments of the inventive concept disclosed herein. The embodiments presented are merely examples and are not intended to limit the scope of the invention.

Moreover, it is noted that the terminology used herein is for the purpose of describing the embodiments only and is not intended to be limiting of the invention. As used herein, singular forms are intended to include the plural forms as well, unless the context clearly indicates otherwise. It will be further understood that the terms “comprises,” “comprising,” “includes” and/or “including” when used in this specification, indicate the presence of stated features, but do not preclude the presence or addition of one or more other non-stated features. As used herein, the term “and/or” indicates any and all combinations of one or more of the associated listed items. It is also noted that in this specification, “connected/coupled” refers to one component not only directly coupling another component but also indirectly coupling another component through an intermediate component.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, an element (also referred to as a feature) described in connection with one embodiment may be used singly or in combination with other elements of another embodiment, unless specifically indicated otherwise.

In the following descriptions, optimizing a refresh operation may indicate minimizing current or power consumption of the refresh operation by minimizing a refresh frequency or maximizing a refresh cycle, while refreshing each memory cell such that data of the memory cell is not deteriorated, in consideration of a data retention time of the memory cell. That is, optimizing a refresh operation may indicate minimizing the refresh frequency or maximizing the refresh cycle, while performing the refresh operation such that data of each memory cell is not deteriorated.

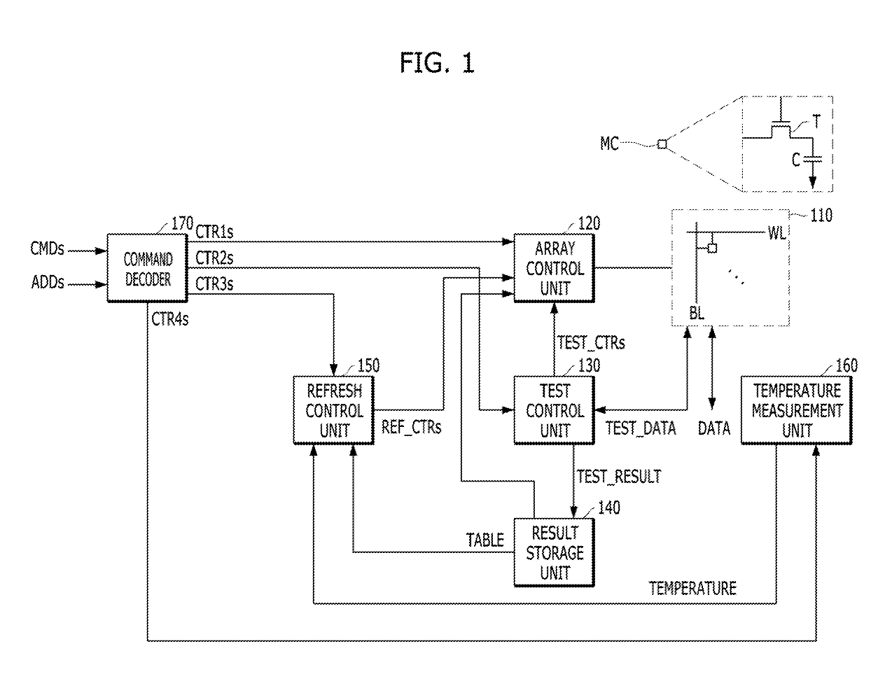

FIG. 1 is a block diagram illustrating a memory device in accordance with an embodiment of the present invention.

Referring to FIG. 1, the memory device may include a cell array 110, an array control unit 120, a test control unit 130, a result storage unit 140, a refresh control unit 150, a temperature measurement unit 160 and a command decoder 170.

The command decoder 170 may receive a plurality of command signals CMDs and a plurality of address signals ADDs, and control an operation of the memory device. For this operation, the command decoder 170 may generate control signals which are decided according to combinations of the plurality of command signals CMDs and the plurality of address signals ADDs, and control the respective components of the memory device. The command decoder 170 may generate first control signals CTR1s for controlling the array control unit 120, second control signals CTR2s for controlling the test control unit 130, third control signals CTR3s for controlling the refresh control unit 150, and fourth control signals CTR4s for controlling the temperature measurement unit 160, according to the combinations of the plurality of commands and address signals CMDs and ADDs.

The cell array 110 may include a plurality of memory cells MC, a plurality of bit lines BL and a plurality of word lines WL. Each of the memory cells MC may include a cell capacitor C and a cell transistor T. For convenience of description, FIG. 1 illustrates only a part of the memory cells MC, the bit lines BL and the word lines WL.

The array control unit 120 may control a row operation and a column operation of the cell array 110. The array control unit 120 may control the row operation to activate or precharge a word line WL in response to the first control signals CTR1s. Furthermore, the array control unit 120 may control the column operation to write data to one or more designated memory cells or to read data stored in one or more designated memory cells, among the plurality of memory cells MC of the cell array 110, in response to the first control signals CTR1s. In FIG. 1, the reference numeral ‘DATA’ may represent data inputted to the cell array 110 or outputted from the cell array 110 according to the control of the array control unit 120.

The array control unit 120 may control a refresh operation of the cell array 110 according to control of the refresh control unit 150. The refresh operation may indicate an operation of activating a designated word line WL for a preset time and then precharging the word line WL, and correspond to one of row operations. The array control unit 120 may refresh the designated word line WL in response to refresh control signals REF_CTRs generated by the refresh control unit 150.

The array control unit 120 may control a test operation for measuring data retention times of the memory cells MC included in the cell array 110, according to control of the test control unit 130. The test operation may include an operation of writing test data generated by the test control unit 130 to the cell array 110, skipping a refresh operation on one or more test cells by a preset number of times, and then reading the data of the test cell such that the data are compared to the test data by the test control unit 130. The test cell may be designated from the plurality of memory cells MC included in the cell array 110, to measure the data retention time. The array control unit 120 may perform a test operation in response to test control signals TEST_CTRs generated by the test control unit 130. In FIG. 1, the reference numeral ‘TEST_DATA’ may represent data transmitted between the test control unit 130 and the cell array 110, and include test data which is generated by the test control unit 130 and written to the memory cells MC, or data which is read from the test cell of the cell array 110 to the test control unit 130.

The test control unit 130 may control the test operation of the array control unit 120 for measuring the data retention times of the plurality of memory cells MC, in response to the plurality of second control signals CTR2s. The test operation may be performed in the following sequence. (1) The test control unit 130 may write test data to the plurality of memory cells MC. (2) The test control unit 130 may sequentially perform a refresh operation on the plurality of memory cells MC at a preset cycle while skipping the refresh operation on one or more test cells by a preset number of times. (3) The test control unit 130 may read data of the test cells, compare the read data to the test data, and detect the data retention times of the test cells according to the comparison results.

According to the data comparison result, the data retention time of the test cell may be decided as follows. For example, suppose that the cycle at which a refresh operation is performed on each of the memory cells MC is tREF, and the number of refresh operations skipped on the test cell is k, where k is a natural number. When data read from the test cell (hereafter, referred to as “test read data”) is equal to the test data, the data retention time of the test cell may be equal to or more than a time during which the refresh operations are skipped, i.e., for a time equal to or more than k×tREF. On the other hand, when the test read data and the test data are different from each other, the data retention time of the test cell may be less than the time for which the refresh operations are skipped. That is, when the data retention time of the test cell is represented by tRETENTION, the former case may have a data retention time tRETENTION according to the relationship of tRETENTION≥k×tREF, and the latter case may have a data retention time tRETENTION according to the relationship of tRETENTION<k×tREF.

When such a method is used, the data retention times of memory cells MC may be measured through the test operation, and the plurality of memory cells MC may be classified depending on the data retention times. For example, when the data retention time of the test cell is measured, the test read data and the test data may be equal to each other in the case where (k−1) refresh operations are skipped, and the test read data and the test data may be different from each other in the case where k refresh operations are skipped. Thus, the data retention time of the test cell may have a data retention time tRETENTION according to the relationship of (k−1)×tREF≤tRETENTION<k×tREF. At this time, among the plurality of memory cells MC, a memory cell having a shorter data retention time than a first reference time may be classified into a weak cell, a memory cell having a longer data retention time than a second reference time longer than the first reference time may be classified into a strong cell, and a memory cell having a data retention time between the first and second reference times may be classified into a normal cell. In addition, the data retention time may be further subdivided to classify the memory cells MC.

The result storage unit 140 may store a measurement result TEST_RESULT of the test control unit 130. The result storage unit 140 may store the measurement result TEST_RESULT in various manners.

The result storage unit 140 in accordance with a first embodiment may store information on a weak cell. The information on the weak cell may include an address of the weak cell and/or one-bit data indicating whether each memory cell is a weak cell. For example, suppose that the data retention times of the memory cells MC are classified on a row (word line) basis, the cell array 110 includes 16 rows, and first to sixteenth row addresses 0 to 15 are used to designate the 16 rows, respectively. When the fifth and tenth row addresses 4 and 9 indicate rows including weak cells (hereafter, referred to as “weak rows”) among the 16 rows, the result storage unit 140 may store fifth and tenth row addresses 4 and 9 corresponding to the weak rows (hereafter, referred to as “weak row addresses”).

Alternatively, the result storage unit 140 may store 16 pieces of one-bit weak information indicating whether the 16 rows are weak rows, respectively. Suppose that weak information corresponding to a weak row is set to 1 and weak information corresponding to a row which is not a weak row is set to 0. In this case, the result storage unit 140 may store the weak information as shown in Table 1.

TABLE 1

| Row | Value of weak information |
|---|---|
| Row with first row address 0 | 0 |
| Row with second row address 1 | 0 |
| Row with third row address 2 | 0 |
| Row with fourth row address 3 | 0 |
| Row with fifth row address 4 | 1 |
| Row with sixth row address 5 | 0 |
| Row with seventh row address 6 | 0 |
| Row with eighth row address 7 | 0 |
| Row with ninth row address 8 | 0 |
| Row with tenth row address 9 | 1 |
| Row with eleventh row address 10 | 0 |
| Row with twelfth row address 11 | 0 |
| Row with thirteenth row address 12 | 0 |
| Row with fourteenth row address 13 | 0 |
| Row with fifteenth row address 14 | 0 |
| Row with sixteenth row address 15 | 0 |

The result storage unit 140 in accordance with a second embodiment may store information on a strong cell. The information on the strong cell may include an address of the strong cell and/or one-bit data indicating whether each memory cell is a strong cell. The information on the strong cell may be stored in the form of a row address of a row including the strong cell (hereafter, referred to as a “strong row”), or stored as one-bit data indicating whether each row is a strong row.

The result storage unit 140 in accordance with a third embodiment may store information on weak and strong cells. The information on the weak and strong cells may include addresses of the weak and strong cells and/or data indicating which memory cells are weak cells or strong cells. The information on the weak and strong cells may be stored in a similar manner to the information on the weak cells and the information on the strong cells.

The result storage unit 140 in accordance with a fourth embodiment may store information obtained by classifying the memory cells MC according to the data retention times thereof. The result storage unit 140 in accordance with the fourth embodiment may store information on the data retention times of the memory cells as shown in Table 2.

TABLE 2

| Data retention time | Row address |
|---|---|
| Less than 1 × tREF | 4, 9 |
| 1 × tREF or more, less than 2 × tREF | 0, 5, 8, 10, 15 |
| 2 × tREF or more, less than 3 × tREF | 1, 3, 6, 7, 11 |
| 3 × tREF or more, less than 4 × tREF | 2, 12, 14 |
| 4 × tREF or more | 13 |

The magnitudes of periods of the data retention times, the number of periods and the classification of the row addresses in Table 2 are only an example, and may be changed depending on design.

The result storage unit 140 may include a nonvolatile memory, a plurality of dummy cells, a plurality of latches or a plurality of fuses. The result storage unit 140 may store the measurement result TEST_RESULT corresponding to the data retention times for the memory cells MC in the nonvolatile memory, the plurality of dummy cells or the plurality of latches in the form of one or more of the first to fourth embodiments. The measurement result TEST_RESULT stored in the result storage unit 140 may be outputted as a result information TABLE.

The refresh control unit 150 may control the array control unit 120 to refresh the plurality of memory cells MC according to control of the command decoder 170, and optimize the refresh operations of the plurality of memory cells using the result information TABLE provided from the result storage unit 140. The refresh control unit 150 may control the refresh operations in response to the third control signals CTR3s, and adjust a refresh frequency or cycle of the memory cells MC by referring to the result information TABLE.

The refresh control unit 150 may optimize the refresh operation in various manners. For example, the refresh control unit 150 may lower the refresh frequency of weak cells or increase the refresh cycle of the weak cells, and correct the data of the weak cells. The data of the weak cells may be corrected using an error correction code (ECC).

The refresh control unit 150 may decrease the refresh cycle of the weak cells to the first reference time or less, and increase the refresh cycle of the strong cells to the second reference time or more, based on the result information TABLE, thereby minimizing the refresh frequency.

The refresh control unit 150 may increase the refresh frequency as a temperature measured by the temperature measurement unit 160 rises, and decrease the refresh frequency as the temperature measured by the temperature measurement unit 160 falls.

The temperature measurement unit 160 may measure the temperature of the cell array 110 or a region adjacent to the cell array 110 according to control of the command decoder 170, and output temperature information TEMPERATURE to the refresh control unit 150. The temperature measurement unit 160 may measure the temperature of the cell array 110 or the region adjacent to the cell array 110 in response to the fourth control signals CTR4s, convert the measured temperature into the temperature information TEMPERATURE of multi-bit digital codes, and output the temperature information TEMPERATURE of multi-bit digital codes to the refresh control unit 150. Generally, the data retention time of the memory cell MC may be adjusted inversely proportional to the operation temperature of the memory cell MC. In other words, the data retention time may decrease as the temperature rises, and increase as the temperature falls. By adjusting the refresh frequency according to the temperature information TEMPERATURE, the refresh frequency and the refresh operation can be optimized. For example, the refresh control unit 150 may decrease the refresh cycle as the temperature rises, and increase the refresh cycle as the temperature falls.

The refresh control unit 150 may control the array control unit 120 to refresh the memory cells MC. At this time, the refresh control unit 150 may optimize the number of refresh operations by adjusting the refresh cycle using the result information TABLE and the temperature information TEMPERATURE, depending on the data retention times of the respective memory cells MC. Optimizing of the number of refresh operations may minimize the number of refresh operations, also referred to hereafter as the refresh number, while managing the data of all the memory cells MC without a loss. Because a refresh operation generally requires high current and power consumption, when the data of the memory cells MC can be stably retained while optimizing the refresh number or frequency the current and power consumption can be substantially reduced. Hence, the overall performance of the memory device can be improved.

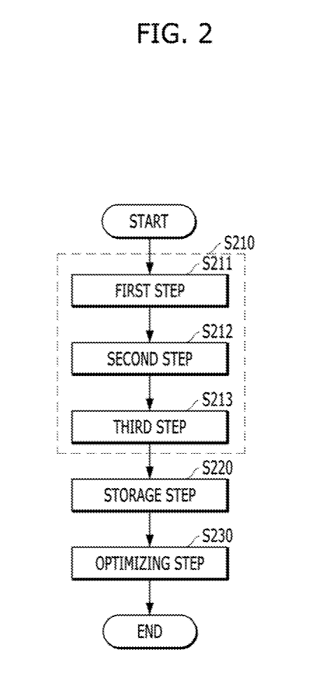

FIG. 2 is a flowchart of an operating method of a memory device in accordance with an embodiment of the present invention.

Referring to FIG. 2, the operating method of the memory device may include a test step S210, a storage step S220 and an optimizing step S230.

The test step S210 may include performing a test operation for measuring data retention times of a plurality of memory cells. The test step S210 may include a first step S211 of writing test data to the plurality of memory cells, a second step S212 of skipping a refresh operation on a test cell by a preset number of times, and a third step S213 of detecting the data retention time of the test cell by comparing test read data and the test data. The data retention times may be classified and stored as described with reference to FIG. 1.

The storage step S220 may include storing a result of the test operation of the test step S210 in a nonvolatile memory, a plurality of dummy cells, a plurality of latches or a plurality of fuses.

The optimizing step S230 may include minimizing a refresh frequency of the plurality of memory cells using the stored result. The method for minimizing or optimizing the refresh frequency may be performed in the same manner as described with reference to FIG. 1.

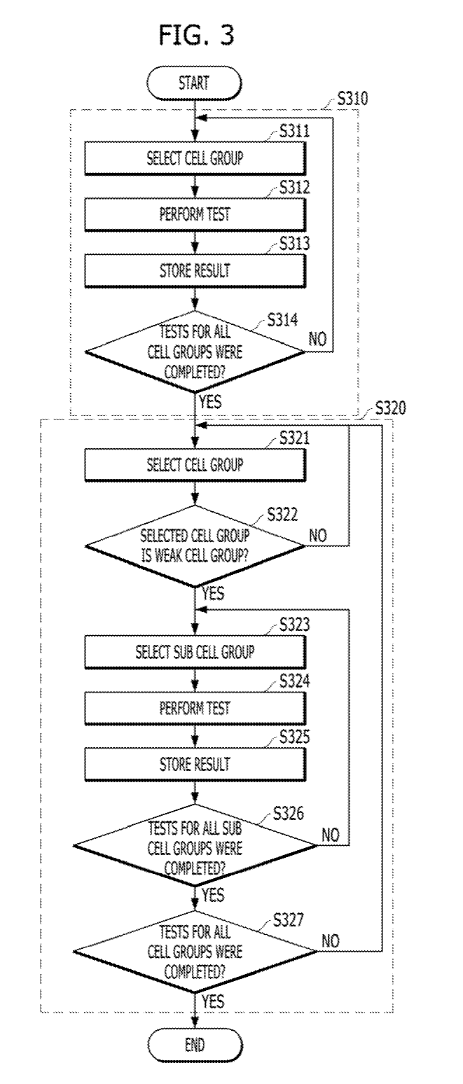

Referring to FIGS. 3 to 7, the test operation of the memory device may be described in more detail.

FIG. 3 is a flowchart of a test operation method in accordance with an embodiment of the present invention.

Referring to FIG. 3, the test operation method may include a first detection step S310 and a second detection step S320.

At the first detection step S310, a plurality of memory cells may be divided into cell groups each including memory cells included in two or more rows, in order to perform a test operation. For example, when the cell array 110 includes 16 rows, the 16 rows may be divided into four cell groups each including four rows, and a test operation may be performed for each of the cell groups. During the first detection step S310, a cell group on which a test operation is not performed may be selected at step S311, a test operation may be performed on the selected cell group at step S312, and a measurement result may be stored at step S313. When the test operation on the selected cell group at step S312 and the storing of the reset result at step S313 were completed, it is determined whether test operations on all of the cell groups are completed at step S314. When the test operations on all of the cell groups were completed (YES at step S314), the test operation method may proceed to the second detection step S320. Otherwise (NO at step S314), the first detection step S310 from step S311 to step S314 is repeatedly performed until the test operations on all of the cell groups are completed.

At the second detection step S320, the cell group detected at the first detection step S310 may be divided into sub cell groups each including memory cells included in one or more rows, in order to perform a test operation. For example, at the second detection step S320, a cell group in which a weak cell was detected, among the four cell groups tested at the first detection step S310, may be divided into four sub cell groups each including one row, in order to perform a test operation. During the second detection step S320, a cell group may be selected at step S321. Then, it is determined whether the selected cell group was detected as a cell group including a weak cell (hereafter, referred to as “weak cell group”) at the first detection step S310, at step S322. When the selected cell group was detected as a weak cell group (YES at step S322), the test operation method may proceed to step S323 to select a sub cell group. Otherwise (NO at step S322), the test operation method may return to step S321 to select another cell group.

After the sub cell group is selected at step S323, a test operation may be performed on the selected sub cell group at step S324, and a measurement result may be stored at step S325. When the test operation on the selected cell group at step S324 and the storing of the measurement result at step S325 were completed, it is determined whether test operations on all of the sub cell groups are completed at step S326. When the test operations on all of the sub cell groups were completed (YES at step S326), it is determined whether the test operations on all of the cell groups were completed at step S327. Otherwise (NO at step S326), steps S323 to S326 are repeatedly performed until the test operations on all of the sub cell groups are completed. When the test operations on all of the cell groups were completed (YES at step S327), the second detection step S320 may be ended. Otherwise, the second detection step S320 from step S321 to step S327 is repeatedly performed until the test operations on all of the cell groups are completed.

The test operation method described with reference to FIG. 3 may include dividing the plurality of rows into row groups each including two or more rows, performing a first test operation on the row groups, and selectively performing a second test operation on only a row group in which a weak cell is detected, among the row groups. When a test operation is performed in such a manner, the test operation may be performed at higher speed than when a test operation is performed on each of the rows from the beginning. When the data retention time is measured up to only the row group unit, the test time can be further reduced.

For example, suppose that one weak row is present in a memory device including 16 rows, and that a time required for performing one test operation is tTEST, regardless of whether one row or one row group is tested. In this case, a time required for detecting a weak row by individually testing the 16 rows is a minimum of 16×tTEST. However, when only the rows included in a weak row group are separately tested after a test operation is performed on the row groups each including four rows, a time required for detecting a weak row may be 8×tTest, i.e., equal to 4×tTEST (time required for testing four row groups) plus 4×tTEST (time required for testing four rows of weak row group)).

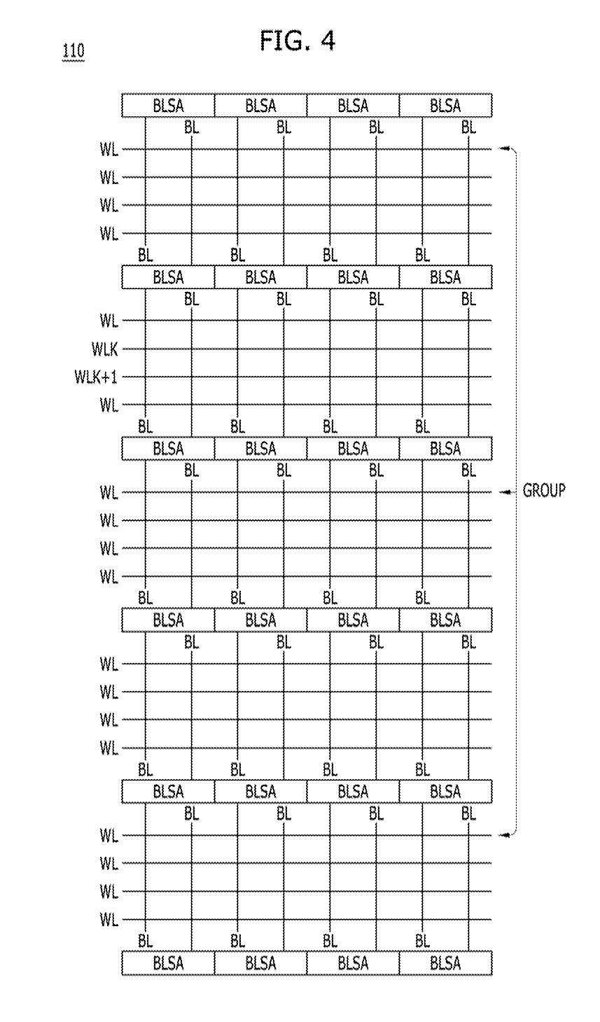

FIG. 4 is a diagram describing a test operation method in accordance with a first embodiment of the present invention.

Referring to FIG. 4, the cell array 110 may include a plurality of word lines WL, a plurality of bit lines BL and a plurality of bit line sense amplifiers BLSA. The memory cells may be located at the respective intersections between the word lines WL and the bit lines BL, and are not illustrated in FIG. 4. The cell array 110 illustrated in FIG. 4 may have an open bit line architecture. When two or more word lines WLk and WLk+1 sharing a bit line sense amplifier BLSA in the cell array 110 are simultaneously activated, data of memory cells coupled to the word lines may collide with each other. However, when word lines which do not share a bit line sense amplifier BLSA are simultaneously activated, data of memory cells coupled to the word lines may not collide with each other.

Based on the above-described characteristic, the test operation method in accordance with the first embodiment may bind word lines which do not share a bit line sense amplifier BLSA, into one row group, and then perform a test operation. FIG. 4 illustrates an example of a row group GROUP including three rows. During a test operation, the memory cells included in one row group may be simultaneously tested. During the test operation, (1) test data may be written to all of the memory cells, (2) a refresh operation on a selected row group may be skipped a preset number of times, and (3) data of the memory cells included in the selected row group may be read and compared to the test data. When the data of the memory cells included in the selected row group are read, all of the word lines included in the selected row group may be simultaneously activated, and the data of the memory cells coupled to the activated word lines may be outputted as test read data at a time. The test read data may include compressed data obtained by compressing the data outputted from the respective memory cells.

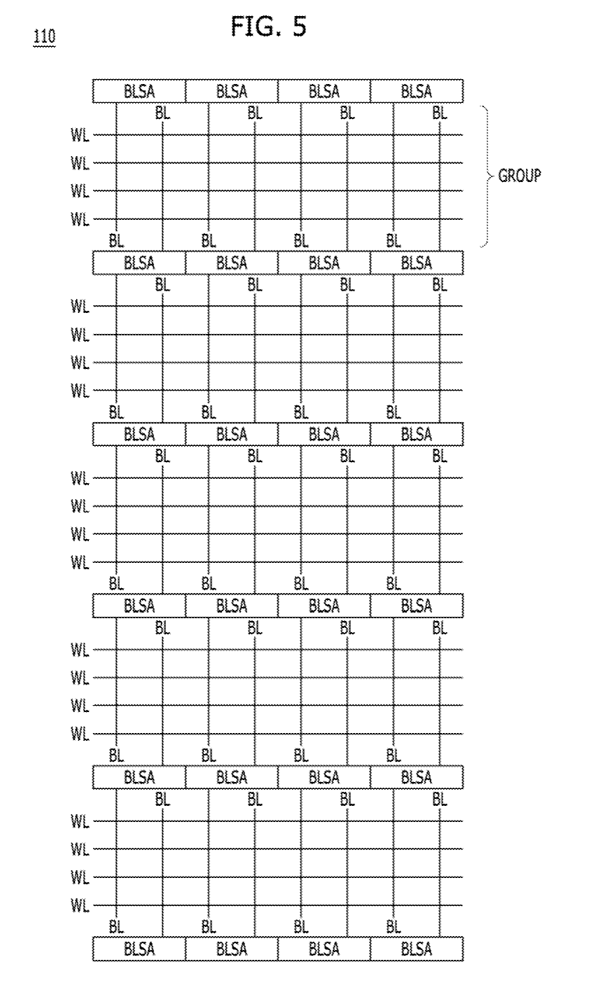

FIG. 5 is a diagram describing a test operation method in accordance with a second embodiment of the present invention.

Referring to FIG. 5, the cell array 110 may include a plurality of word lines WL, a plurality of bit lines BL and a plurality of bit line sense amplifiers BLSA. The memory cells may be located at the respective intersections between the word lines WL and the bit lines BL, and are not illustrated in FIG. 5. The cell array 110 illustrated in FIG. 5 may have an open bit line architecture.

The test operation method in accordance with the second embodiment may bind word lines sharing a bit line BL into one row group and then perform a test operation. FIG. 5 illustrates an example of a row group GROUP.

During a test operation, memory cells included in one row group may be simultaneously tested. During the test operation, (1) test data may be written to all of the memory cells, (2) a refresh operation on a selected row group may be skipped a preset number of times, and (3) the word lines WL included in the selected row group may be all activated to change the potential of the bit line BL. After a preset time has elapsed, test read data may be decided according to the potential of the bit line BL, and compared to the test data in order to detect whether the selected row group includes a weak cell.

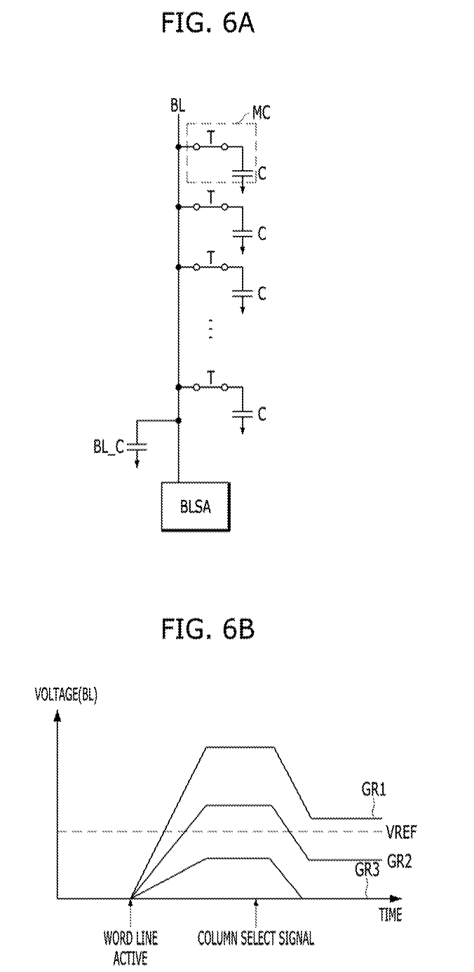

FIG. 6A is a diagram illustrating a state in which a plurality of memory cells MC are electrically coupled to one bit line BL.

In FIG. 6A, cell transistors T are illustrated in the form of turned-on switches. As illustrated in FIG. 6A, two or more cell capacitors C may be electrically coupled to one bit line at the same time, during a test operation. When the capacitance of the bit line BL is represented by BL_C, the voltage of the bit line BL may be changed by charge sharing between the cell capacitors C and the capacitance BL_C, with time. In FIG. 6A, an illustration of the word lines is omitted.

FIG. 6B is a graph illustrating how the voltage of the bit line BL is changed with time, depending on the data retention times of the memory cells MC of FIG. 6A.

Referring to FIG. 6B, a first graph GR1 may represent a first case CASE1 in which the voltage of the bit line is changed with time when the average data retention time of the memory cells MC is longer than that of a reference memory cell MC. In the first case CASE1, all or part of the memory cells MC may be determined as strong cells which have a longer data retention time than the reference memory cell MC. A second graph GR2 may represent a second case CASE2 in which the voltage of the bit line BL is changed with time when the average data retention time of the memory cells MC is similar to that of the reference memory cell MC. A third graph GR3 may represent a third case CASE3 in which the voltage of the bit line BL is changed with time when the average data retention time of the memory cells MC is shorter than that of the reference memory cell MC. In the third case CASE3, all or part of the memory cells MC may be determined as weak cells.

Referring to the first to third graphs GR1 to GR3, the voltage change of the bit line BL per time and the maximum value of the bit line voltage may differ depending on the average data retention time of the memory cells MC. The reason may be described as follows. The amount of charge stored in an ideal memory cell MC is retained regardless of time, but the amount of charge stored in an actual cell capacitor C gradually decreases with time. However, the amount of charge stored in the cell capacitor C slowly decreases as the data retention time is increased. In the case of a weak cell, the amount of charge stored in the cell capacitor C quickly decreases. Therefore, when the memory cells MC are coupled to the bit line BL, the total amount of charge stored in the cell capacitors C of the memory cells MC is the largest in the first case CASE1, and the smallest in the third case CASE3.

As the difference in charge amount between the memory cells MC and the bit line BL is increased, the charge is quickly transferred. Therefore, the voltage change of the bit line BL per time is the largest in the first graph GR1. Furthermore, as the amount of charge stored in the memory cells MC is increased, a large amount of charge is shared by the bit line BL while the charge is completely distributed. Therefore, the maximum value of the voltage of the bit line BL is the largest in the first graph GR1. At this time, when the first and second cases CASE1 and CASE2 have a higher voltage level than a reference voltage level VREF and the third case CASE3 has a lower voltage level than the reference voltage level VREF at a point of time that a column select signal is enabled, high data “1” may be outputted from the sense amplifier BLSA in the first and second cases CASE1 and CASE2, and low data “0” may be outputted from the sense amplifier BLSA in the third case CASE3. Since the high data “1” are written to the memory cells MC as an initial value, test read data and test data may be compared to determine whether weak cells are included in a row group.

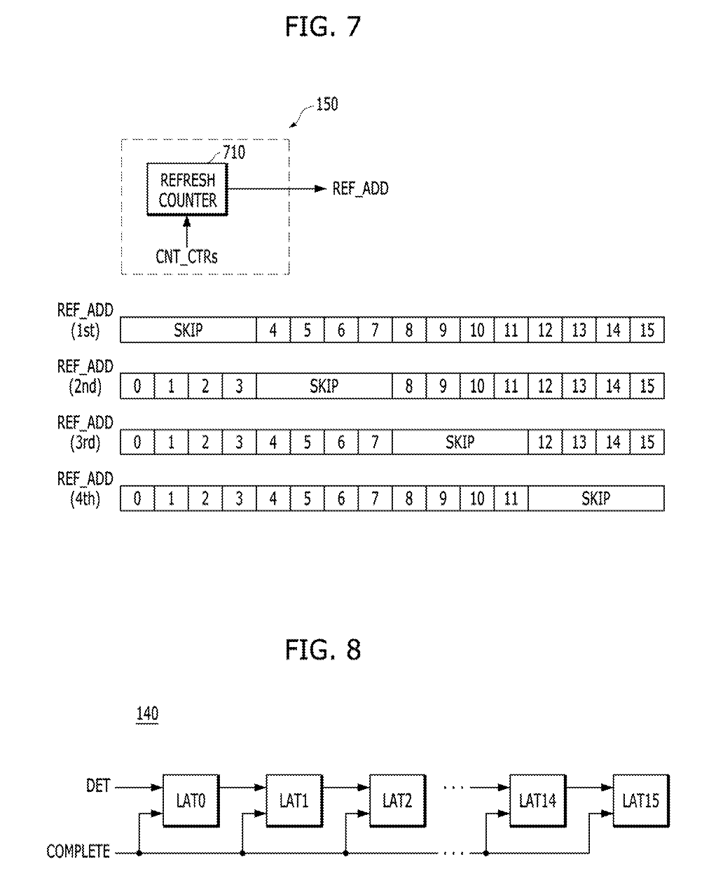

FIG. 7 is a diagram describing a test operation method in accordance with a third embodiment of the present invention.

Referring to FIG. 7, the refresh control unit 150 may include a refresh counter 710. During a refresh operation, a word line corresponding to a refresh address REF_ADD generated by the refresh counter 710 may be refreshed. During a test operation, the refresh counter 710 may skip a preset value by a preset number of times, such that a refresh operation on a test cell is skipped the preset number of times. The operation of the refresh counter 710 may be controlled according to counting control signals CNT_CTRs. For reference, the refresh address REF_ADD may correspond to the refresh control signals REF_CTRs of FIG. 1, and the counting control signals CNT_CTRs may correspond to the third control signals CTR3s provided from the command decoder 170 of FIG. 1.

FIG. 7 illustrates the case in which the number of word lines included in the cell array 110 is 16, first to sixteenth refresh addresses REF_ADD of 0 to 15 are used to designate the 16 word lines, a row group includes four word lines, and a refresh operation on a selected row group is skipped once during a test operation.

In this case, during a first test operation, a refresh operation on the four word lines corresponding to the first to fourth refresh addresses REF_ADD of 0 to 3 may be skipped once. During a second test operation, a refresh operation on the four word lines corresponding to the fifth to eighth refresh addresses REF_ADD of 4 to 7 may be skipped once. During a third test operation, a refresh operation on the four word lines corresponding to the ninth to twelfth refresh addresses REF_ADD of 8 to 11 may be skipped once. During a fourth test operation, a refresh operation on the four word lines corresponding to the thirteenth to sixteenth refresh addresses REF_ADD of 12 to 15 may be skipped once.

Referring to FIGS. 8 to 11, a method for storing a measurement result and a method for transmitting stored result information TABLE will be described in detail.

FIG. 8 is a block diagram describing a method for storing a measurement result TEST_RESULT in accordance with a first embodiment of the present invention. In FIG. 8, a detection signal DET may be information on weak cells, which is contained in the measurement result TEST_RESULT of FIG. 1.

Referring to FIG. 8, the result storage unit 140 may include a plurality of latches corresponding to the number of rows or row groups included in the cell array 110, to store the measurement result. Hereafter, the case in which 16 latches LAT0 to LAT15 of which the number is equal to the number of rows (or word lines) included in the cell array 110 are used to store the measurement result will be described.

The plurality of latches LAT0 to LAT15 may be coupled in series, the first latch LAT0 may receive and store the detection signal DET, and the plurality of latches LAT0 to LAT15 may shift values stored therein whenever a test completion signal COMPLETE is enabled.

The test completion signal COMPLETE may be enabled whenever a test operation on test cells is completed. For example, when the memory device performs a test operation on a row basis, the test completion signal COMPLETE may be enabled whenever a test operation on one row is completed.

The detection signal DET may indicate whether a test cell is a weak cell or strong cell. The detection signal DET may have a value of ‘1’ when the test cell is a weak cell (or strong cell), and have a value ‘0’ when the test cell is not a weak cell (or strong cell), depending on the test operation method. On the contrary, the detection signal DET may have a value of ‘0’ when the test cell is a weak cell (or strong cell), and have a value ‘1’ when the test cell is not a weak cell (or strong cell). Therefore, the detection signal DET may be stored and used as one-bit data indicating that the memory cell is a weak cell (or strong cell).

Hereafter, an operation of storing a measurement result indicating that fifth and tenth rows are detected as weak rows including weak cells during a test operation will be described. The initial values stored in the plurality of latches LAT0 to LAT15 are ‘0’, and the values stored in the latches LAT15 to LAT0 may be consecutively expressed as a 16-bit binary number. [Table 3] shows values stored in the respective latches when 16 test operations were completed. In Table 3, L15 to L0 may represent the values stored in the respective latches LAT15 to LAT0. As a result, among the latches LAT15 to LAT0, the fifth and tenth latches LAT4 and LAT9 may store the measurement result respectively corresponding to the fifth and tenth rows including the weak cells.

TABLE 3

| | L15 | L14 | L13 | L12 | L11 | L10 | L9 | L8 | L7 | L6 | L5 | L4 | L3 | L2 | L1 | L0 |
|---|---|---|---|---|---|---|---|---|---|---|---|---|---|---|---|---|
| 1 | 0 | 0 | 0 | 0 | 0 | 0 | 0 | 0 | 0 | 0 | 0 | 0 | 0 | 0 | 0 | 0 |
| 2 | 0 | 0 | 0 | 0 | 0 | 0 | 0 | 0 | 0 | 0 | 0 | 0 | 0 | 0 | 0 | 0 |
| 3 | 0 | 0 | 0 | 0 | 0 | 0 | 0 | 0 | 0 | 0 | 0 | 0 | 0 | 0 | 0 | 0 |
| 4 | 0 | 0 | 0 | 0 | 0 | 0 | 0 | 0 | 0 | 0 | 0 | 0 | 0 | 0 | 0 | 0 |
| 5 | 1 | 0 | 0 | 0 | 0 | 0 | 0 | 0 | 0 | 0 | 0 | 0 | 0 | 0 | 0 | 0 |
| 6 | 0 | 1 | 0 | 0 | 0 | 0 | 0 | 0 | 0 | 0 | 0 | 0 | 0 | 0 | 0 | 0 |
| 7 | 0 | 0 | 1 | 0 | 0 | 0 | 0 | 0 | 0 | 0 | 0 | 0 | 0 | 0 | 0 | 0 |
| 8 | 0 | 0 | 0 | 1 | 0 | 0 | 0 | 0 | 0 | 0 | 0 | 0 | 0 | 0 | 0 | 0 |
| 9 | 0 | 0 | 0 | 0 | 1 | 0 | 0 | 0 | 0 | 0 | 0 | 0 | 0 | 0 | 0 | 0 |
| 10 | 1 | 0 | 0 | 0 | 0 | 1 | 0 | 0 | 0 | 0 | 0 | 0 | 0 | 0 | 0 | 0 |
| 11 | 0 | 1 | 0 | 0 | 0 | 0 | 1 | 0 | 0 | 0 | 0 | 0 | 0 | 0 | 0 | 0 |
| 12 | 0 | 0 | 1 | 0 | 0 | 0 | 0 | 1 | 0 | 0 | 0 | 0 | 0 | 0 | 0 | 0 |
| 13 | 0 | 0 | 0 | 1 | 0 | 0 | 0 | 0 | 1 | 0 | 0 | 0 | 0 | 0 | 0 | 0 |
| 14 | 0 | 0 | 0 | 0 | 1 | 0 | 0 | 0 | 0 | 1 | 0 | 0 | 0 | 0 | 0 | 0 |
| 15 | 0 | 0 | 0 | 0 | 0 | 1 | 0 | 0 | 0 | 0 | 1 | 0 | 0 | 0 | 0 | 0 |
| 16 | 0 | 0 | 0 | 0 | 0 | 0 | 1 | 0 | 0 | 0 | 0 | 1 | 0 | 0 | 0 | 0 |

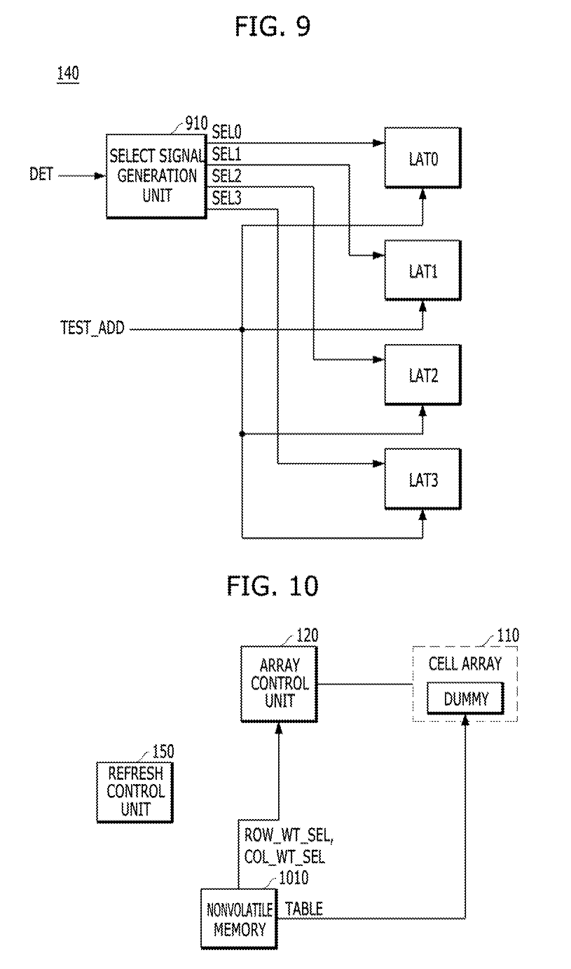

FIG. 9 is a block diagram describing a method for storing a measurement result TEST_RESULT in accordance with a second embodiment of the present invention. In FIG. 9, a detection signal DET and a test address TEST_ADD may be information on weak cells, which is contained in the measurement result TEST_RESULT of FIG. 1.

Referring to FIG. 9, the result storage unit 140 may include a select signal generation unit 910 and one or more latches LAT0 to LAT3. The latches LAT0 to LAT3 may store the test address TEST_ADD of multi-bit address included in the measurement result TEST_RESULT, in response to select signals SEL0 to SEL3. The select signal generation unit 910 may generate the select signals SEL0 to SEL3 corresponding to the respective latches LAT0 to LAT3, and enable one of the select signals SEL0 to SEL3. The select signal generation unit 910 may enable the select signal SEL0 among the select signals SEL0 to SEL3 at the initial stage, and change an enabled one of the select signals SEL0 to SEL3 whenever the detection signal DET is enabled. The number of times that the detection signal DET is enabled and the enabled select signal among the select signals SEL0 to SEL3 may be shown in Table 4.

TABLE 4

| DET enable count | SEL0 | SEL1 | SEL2 | SEL3 |
|---|---|---|---|---|
| 0 | Enabled | Disabled | Disabled | Disabled |
| 1 | Disabled | Enabled | Disabled | Disabled |
| 2 | Disabled | Disabled | Enabled | Disabled |
| 3 | Disabled | Disabled | Disabled | Enabled |

Among the latches LAT0 to LAT3, a latch may store the test address TEST_ADD when the select signal corresponding to the latch is enabled. The test address TEST_ADD may indicate the address of a row in which a test operation is performed.

Hereafter, an operation of performing a test operation on a row basis and storing a measurement result indicating that fifth and tenth rows are detected as weak rows including weak cells will be described. The detection signal DET may be disabled during the first to fourth test operations, and enabled during the fifth test operation. Therefore, after the test address TEST_ADD of the row on which the fifth test operation was performed may be stored in the latch LAT0, the select signal SEL0 may be disabled and the select signal SEL11 may be enabled. Furthermore, the detection signal DET may be disabled during the sixth to ninth test operations, and enabled during the tenth test operation. Therefore, after the test address TEST_ADD of the row on which the tenth test operation was performed may be stored in the latch LAT1, the select signal SEL1 may be disabled and the select signal SEL2 may be enabled. The detection signal DET may be disabled during the eleventh to sixteenth test operations. Therefore, as the result of the test operation, the test address TEST_ADD of the row on which the fifth test operation was performed may be stored in the latch LAT0, and the test address TEST_ADD of the row on which the tenth test operation was performed may be stored in the latch LAT1.

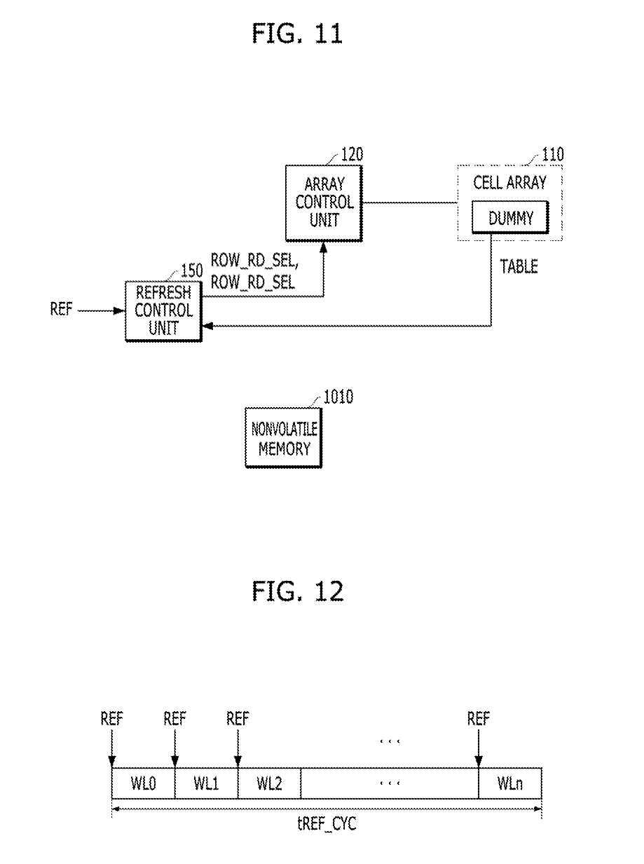

FIGS. 10 and 11 are diagrams for describing a method for storing and transmitting result information TABLE stored in the result storage unit 140 in accordance with an embodiment of the present invention. Referring to FIGS. 10 and 11 illustrating only a part of the components of the memory device of FIG. 1, the method for storing and transmitting the result information TABLE will be described. In the following descriptions, the result storage unit 140 may include a nonvolatile memory 1010, and the cell array 110 may include a dummy cell region DUMMY.

FIG. 10 is a diagram describing an operation of transmitting the result information TABLE stored in the nonvolatile memory 1010 to the dummy cell region DUMMY.

Referring to FIG. 10, the memory device may use the nonvolatile memory 1010 and the dummy cell region DUMMY which is a part of the cell array 110, in order to store a measurement result. In an embodiment, the nonvolatile memory 1010 may include one of nonvolatile memories such as an Array E-fuse (ARE) circuit, a laser fuse circuit, a NAND flash memory, a NOR flash memory, a Magnetic Random Access Memory (MRAM), a Spin Transfer magnetic Random Access Memory (STT-MRAM), a Resistive Random Access Memory (ReRAM) and a Phase Change Random Access Memory (PCRAM).

A measurement result obtained by measuring a data retention time of a memory cell may be programmed to the nonvolatile memory 1010, as the result information TABLE. During a boot-up operation, the result information TABLE stored in the nonvolatile memory 1010 may be transmitted and stored into the dummy cell region DUMMY. During a refresh operation, the result information TABLE stored in the dummy cell region DUMMY may be transmitted to the refresh control unit 150 and used to control the refresh operation.

The result information TABLE stored in the nonvolatile memory 1010 may be all transmitted to the dummy cell region DUMMY through a plurality of transmission operations. The number of bits contained in data which are transmitted from the nonvolatile memory 1010 to the dummy cell region DUMMY through one transmission operation may be equal to the maximum number of bits contained in data which can be inputted to or outputted from the cell array 110 through one column operation.

When the operation of transmitting the result information TABLE stored in the nonvolatile memory 1010 to the dummy cell region DUMMY is started, (1) data containing a preset number of bits may be read from the nonvolatile memory 1010. At this time, the preset number of bits may be equal to the number of bits contained in data which can be transmitted to the dummy cell region DUMMY from the nonvolatile memory 1010 through one transmission operation. (2) When the data are completely read from the nonvolatile memory 1010, the read data may be transmitted as the result information TABLE to the dummy cell region DUMMY. Simultaneously, the nonvolatile memory 1010 may transmit row and column select information ROW_WT_SEL and COL_WT_SEL to the array control unit 120. The row select information ROW_WT_SEL may include a row address for selecting a row to which the result information TABLE is to be written, and the column select information COL_WT_SEL may include a column address for selecting a column to which the result information TABLE is to be written. (3) The result information TABLE transmitted to the dummy cell region DUMMY may be written to a dummy cell selected by the row and column select information ROW_WT_SEL and COL_WT_SEL transmitted from the nonvolatile memory 1010. The column select information COL_WL_SEL transmitted to the array control unit 120 from the nonvolatile memory 1010 may be changed whenever the result information TABLE is transmitted, and the row select information ROW_WT_SEL may be changed when the result information TABLE is written to the whole selected row.

For example, suppose that 64-bit data can be inputted to or outputted from the cell array 110 at a time, and 64*x-bit data can be stored in one word line where x is a natural number. In this case, 64-bit data may be read from the nonvolatile memory 1010 at a time, transmitted as the result information TABLE, and written to the dummy cell region DUMMY. The value of the column select information COL_WL_SEL transmitted to the array control unit 120 may be changed whenever the result information TABLE is transmitted once, and the value of the row select information ROW_WT_SEL may be changed after the column select information COL_WT_SEL is changed (x−1) times or the result information TABLE is written to a dummy cell coupled to one word line.

FIG. 11 is a diagram describing an operation of transmitting the result information TABLE stored in the dummy cell region DUMMY to the refresh control unit 150 during a refresh operation.

Referring to FIG. 11, during the refresh operation, the result information TABLE stored in the dummy cell region DUMMY may be transmitted to the refresh control unit 150 and used to adjust a refresh frequency or cycle. When a refresh command REF is applied, the refresh control unit 150 may generate row and column select information ROW_RD_SEL and COL_RD_SEL and transmit the generated information to the array control unit 120, in order to read and transmit the result information TABLE stored in the dummy cell region DUMMY during the refresh operation. The array control unit 120 may transmit data of a dummy cell selected by the row and column select information ROW_RD_SEL and COL_RD_SEL to the refresh control unit 150. When the refresh command REF is applied one or more times, the refresh control unit 150 may change the row and column select information ROW_RD_SEL and COL_RD_SEL, receive result information TABLE stored in a different location of the dummy cell region DUMMY, and use the received information to adjust the refresh frequency and cycle.

Referring to FIGS. 12 to 15, a method for adjusting the refresh frequency or cycle using the result information transmitted to the refresh control unit 150 may be described in more detail. In FIG. 12, a plurality of word lines included in the cell array 110 may be represented by the reference numerals ‘WL0’ to ‘WLn’, where n is a natural number.

FIG. 12 is a diagram describing a general refresh operation.

Referring to FIG. 12, when a refresh command REF is applied, one word line may be refreshed. During the general refresh operation, the word lines WL0 to WLn may be sequentially and repeatedly refreshed. Refresh cycle tREF_CYC may indicate a period in which the plurality of word lines WL0 to WLn included in the cell array 110 are sequentially refreshed once. Therefore, when the refresh command REF is applied (n+1) times in FIG. 12, all of the word lines WL0 to WLn can be refreshed once.

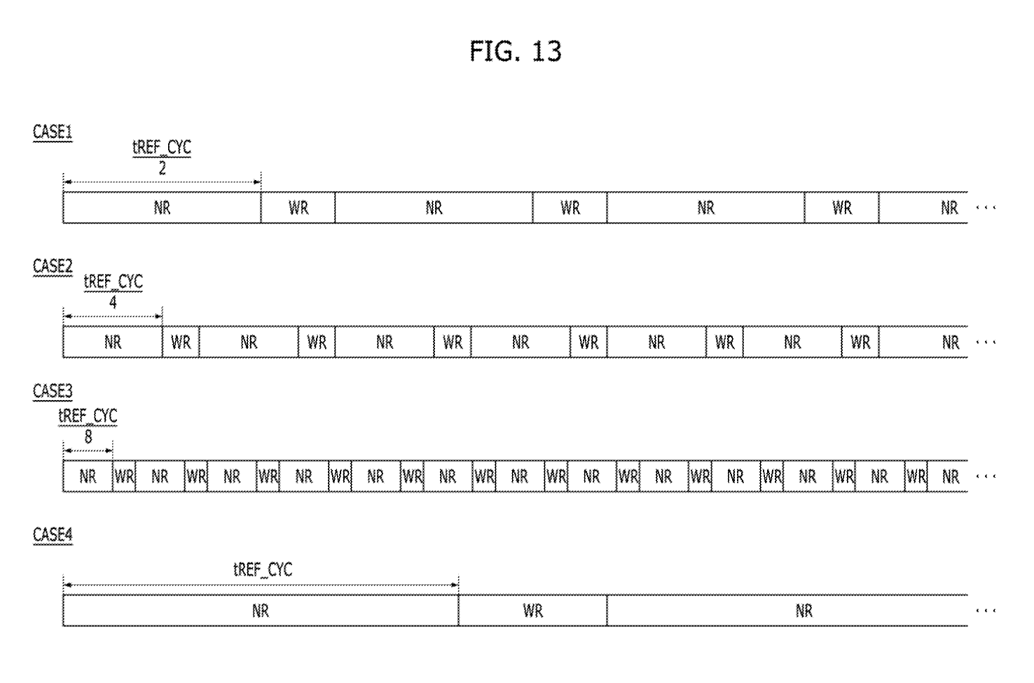

In FIGS. 13 to 15, an illustration of the refresh command REF inputted at a constant cycle may be omitted.

FIG. 13 is a diagram describing a method for adjusting the refresh frequency or cycle of the refresh control unit 150 in accordance with a first embodiment of the present invention.

Referring to FIG. 13, when the result information TABLE includes an address of a weak cell (hereafter, referred to as a “weak address”), the refresh control unit 150 may manage the weak cell by refreshing the weak cell during the refresh cycle. The refresh control unit 150 may control the array control unit 120 to refresh a weak word line using the weak address during the refresh cycle tREF_CYC. A period in which the weak word line is refreshed may be represented by the reference numeral ‘WR’, and a general refresh period may be represented the reference numeral ‘NR’. A general refresh operation may be referred to as a normal refresh operation, and an operation of refreshing a weak word line may be referred to as a weak refresh operation.

In a first case CASE1, the refresh cycle tREF_CYC may be divided into two parts, (1) a normal refresh operation may be performed during the normal refresh period NR of a half of the refresh cycle (tREF_CYC/2), (2) a weak refresh operation may be performed during the weak refresh period WR, and (3) a normal refresh operation may be performed during the normal refresh period NR of tREF_CYC/2.

In a second case CASE2, the refresh cycle tREF_CYC may be divided into four parts, (1) a normal refresh operation may be performed during the normal refresh period NR of a quarter of the refresh cycle (tREF_CYC/4), (2) a weak refresh operation may be performed during the weak refresh period WR, (3) a normal refresh operation may be performed during the normal refresh period NR of tREF_CYC/4, (4) a weak refresh operation may be performed during the weak refresh period WR, (5) a normal refresh operation may be performed during the normal refresh period NR of tREF_CYC/4, (6) a weak refresh operation may be performed during the weak refresh period WR, and (7) a normal refresh operation may be performed during the normal refresh period NR of tREF_CYC/4.

In a third case CASE3, the refresh cycle tREF_CYC may be divided in eight parts, and a weak refresh operation may be performed during the weak refresh period WR whenever a normal refresh operation may be performed during the normal refresh period NR of ⅛ of the refresh cycle (tREF_CYC/8).

In a fourth case CASE4, the refresh cycle tREF_CYC may not be divided, but a weak refresh operation may be performed during the weak refresh period WR whenever a normal refresh operation may be performed during the normal refresh period NR of the refresh cycle tREF_CYC.

The cell array 110 may include two or more weak word lines. In this case, all weak word lines may be refreshed at one weak refresh period, or divided and refreshed at two or more weak refresh periods. For example, suppose that the number of weak word lines is 12, and a refresh operation is performed as in the case CASE2. In this case, 12 weak word lines may be refreshed once at each of the first to third weak refresh periods WR, or four weak word lines may be refreshed once at each of the first to third weak refresh periods WR. Therefore, during one refresh cycle tREF_CYC, 12 weak word lines may be refreshed once.

The number of times that each of the weak word lines is refreshed during one refresh cycle tREF_CYC or the number of parts of the refresh cycle tREF_CYC, which are divided in order to perform a weak refresh operation, may be set in consideration of the data retention times of the respective word lines, the current consumption and power consumption of the refresh operation. Such a method can reduce the whole current and power consumption of the refresh operation while preventing a deterioration in data of the weak word lines. That is, the method can optimize the refresh operation.

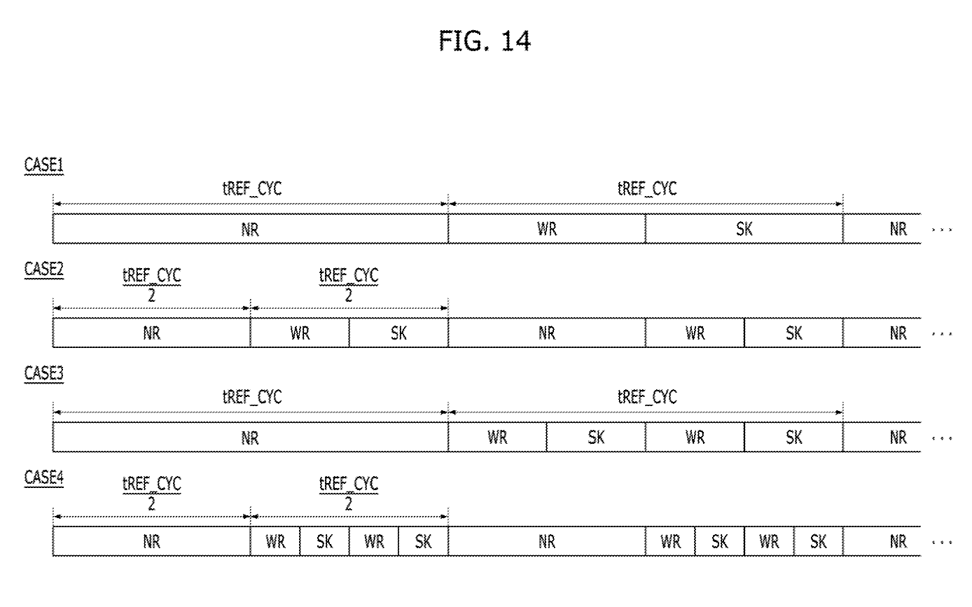

FIG. 14 is a diagram describing a method for adjusting the refresh frequency or cycle of the refresh control unit 150 in accordance with a second embodiment of the present invention.

Referring to FIG. 14, when the result information TABLE includes an address of a weak cell (or a weak address), the refresh control unit 150 may manage the weak cell by refreshing the weak cell during the refresh cycle. The refresh control unit 150 may control the array control unit 120 to refresh a weak word line using the weak address during the refresh cycle tREF_CYC, and skip a refresh operation during a part of the refresh cycle tREF_CYC. A weak refresh period may be represented by the reference numeral ‘WR’, a normal refresh period may be represented by the reference numeral ‘NR’, and a period in which a refresh operation is skipped may be represented by the reference numeral ‘SK’.

In a first case CASE1, the refresh cycle tREF_CYC may not be divided, but a weak refresh operation may be performed during the weak refresh period WR whenever a normal refresh operation may be performed during the normal refresh period NR of one refresh cycle tREF_CYC. When a part of the refresh cycle tREF_CYC is left after the weak refresh operation, a refresh operation may be skipped during the part of the refresh cycle tREF_CYC, i.e., the period SK. Thus, the sum of the period in which the weak refresh operation is performed and the period in which the refresh operation is skipped may correspond to the refresh cycle tREF_CYC.

In a second case CASE2, the refresh cycle tREF_CYC may be divided into two parts, (1) a normal refresh operation may be performed during a half of the refresh cycle (tREF_CYC/2), and (2) a weak refresh operation and a skip operation may be performed during the next half of the refresh cycle (tREF_CYC/2).

In a third case CASE3, the refresh cycle tREF_CYC may not be divided, but a weak refresh operation and a skip operation may be performed whenever one refresh cycle tREF_CYC is completed. At this time, the refresh operation and the skip operation may be alternately performed two or more times during one refresh cycle tREF_CYC. Thus, the sum of the periods in which the weak refresh operations are performed and the periods in which the refresh operations are skipped may correspond to the refresh cycle tREF_CYC.

In a fourth case CASE4, the refresh cycle tREF_CYC may be divided into two parts, (1) a normal refresh operation may be performed during a half of the refresh cycle (tREF_CYC/2), and (2) a weak refresh operation and a skip operation may be alternately performed two or more times during the next half of the refresh cycle (tREF_CYC/2).

The method illustrated in FIG. 14 can decrease the refresh frequency of a memory cell having a long data retention time, and increase the refresh frequency of a memory cell having a shorter data retention time, while skipping a refresh operation during a period in which refresh is not required, thereby optimizing the refresh operation.

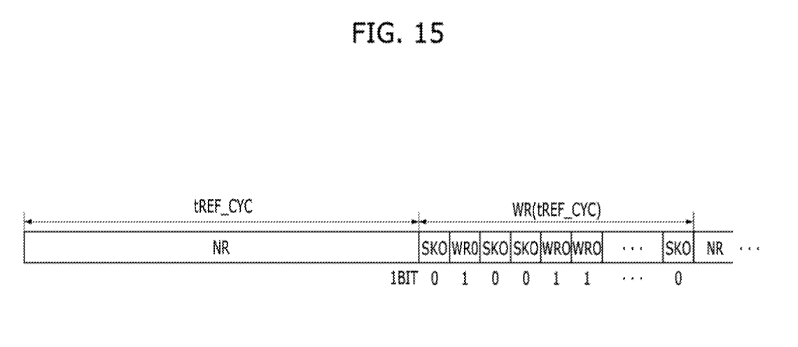

FIG. 15 is a diagram describing a method for adjusting the refresh frequency or cycle of the refresh control unit 150 in accordance with a third embodiment of the present invention.

Referring to FIG. 15, a plurality of bits contained in the result information TABLE may correspond to a plurality of word lines, respectively. When each of the bits is one-bit data indicating whether the corresponding word line is a weak word line, only a weak refresh operation on a weak word line may be performed at a weak refresh period, and refresh operations on word lines except for the weak word line may be skipped, in order to manage weak cells. The refresh control unit 150 may control the array control unit 120 to refresh the weak word line and skip the refresh operations on the other word lines, using the one-bit data during the refresh cycle tREF_CYC.

Hereafter, a normal refresh period may be represented by the reference symbol ‘NR’, a weak refresh period may be represented by the reference symbol ‘WR’, one weak refresh operation may be represented by the reference symbol ‘WRO’, and one skip operation may be represented by the reference symbol ‘SKO’.

During the weak refresh period WR of the refresh operation in FIG. 15, the refresh control unit 150 may perform a weak refresh operation on each word line or skip a refresh operation on the word line, using one-bit data corresponding to the word line. In FIG. 15, 1BIT may represent one-bit data to decide whether to refresh or skip a currently selected word line at the weak refresh period WR. A word line corresponding to one-bit data of ‘1’ may be a weak word line, and a word line corresponding to one-bit data of ‘0’ may not be a weak word line. Therefore, during the weak refresh period WR, when the one-bit data is ‘1’, the corresponding word line may be refreshed for one weak refresh operation WRO, and when the one-bit data is ‘0’, the corresponding word line may be skipped for the one skip operation SKO.

The method illustrated in FIG. 15 can decrease the refresh frequency of a memory cell having a long data retention time, and increase the refresh frequency of a memory cell having a shorter data retention time, while skipping a refresh operation at a period in which refresh is not required, thereby optimizing the refresh operation.

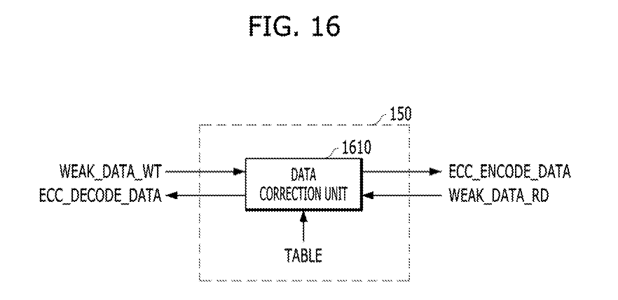

FIG. 16 is a diagram describing a method for adjusting a refresh frequency or cycle by correcting data of a weak cell.

Referring to FIG. 16, the refresh control unit 150 may perform an ECC operation. The refresh control unit 150 may include a data correction unit 1610. The data correction unit 1610 may receive the result information TABLE, and generate ECC encoding data ECC_ENCODE_DATA by encoding data WEAK_DATA_WT written to memory cells indicated by the result information TABLE, or generate ECC decoding data ECC_DECODE_DATA by decoding data WEAK_DATA_RD read from memory cells indicated by the result information TABLE.

That is, the data correction unit 1610 may apply an ECC operation only to a memory cell group having the same row and column addresses as a weak cell. The ECC operation can correct multi-bit data even though an error is present in a part of the multi-bit data. Therefore, when data of a memory cell group including a weak cell are read, the data correction unit can correct the data of the weak cell even though the data was deteriorated.

For reference, the ECC encoding data ECC_ENCODE_DATA may include a parity bit for correcting an error of the write data WEAK_DATA_WT. The read data WEAK_DATA_RD may include data read from a weak cell and a parity bit for correcting an error of the data. The ECC decoding data ECC_DECODE_DATA may include data obtained by correcting an error of the read data WEAK_DATA_RD through an ECC operation.

As described above, since a weak cell has a shorter data retention time, data stored in the weak cell may be deteriorated when the refresh period is longer than the data retention time. However, when an error of the data of the weak cell is corrected through the ECC operation, a refresh operation does not need to be performed according to the data retention time of the weak cell. Therefore, although the refresh period of the weak cell is increased, the weak cell can be managed.

Hereafter, referring to FIG. 1, a method for adjusting a refresh frequency or cycle by increasing the data retention time of a weak cell will be described.

Referring to FIG. 1, when a write operation is performed on a weak cell, the array control unit 120 may raise a voltage level of a write voltage or increase a period in which the write voltage is applied, using the result information stored in the result storage unit 140, compared to when a write operation is performed on another memory cell. The write voltage may indicate a voltage for driving a bit line BL during the write operation. When the voltage level of the write voltage is raised or the period in which the write voltage is applied is increased, a larger amount of charge may be stored in the cell capacitor C. Therefore, a longer time may be required until the data stored in the weak cell is deteriorated compared to if a normal voltage or normal period were used. In this way, the data retention time of the weak cell can be temporarily increased.

As described above, since a weak cell has a shorter data retention time, data stored in the weak cell may be deteriorated when the refresh cycle is longer than the data retention time. When the data retention time of the weak cell is increased by raising the voltage level of the write voltage or the period in which the write voltage is applied during the write operation, the weak cell can be managed even though the refresh cycle of the weak cell is increased.

In accordance with the present embodiments, the memory device and the operating method thereof can measure data retention times of a plurality of memory cells, store the measurement result, and optimize a refresh operation on the plurality of memory cells according to the stored measurement result, thereby reducing current consumption and power consumption of the refresh operation while properly managing weak cells.

Although various embodiments have been described for illustrative purposes, it will be apparent to those skilled in the art that various changes and modifications may be made without departing from the spirit and scope of the invention as defined in the following claims.

What is claimed is:

1. An operating method of a memory device including a plurality of memory cells, comprising:
measuring data retention times of at least a portion of the plurality of memory cells; and
optimizing a refresh operation on the plurality of memory cells using the measurement result.

2. The operating method of claim 1, further comprising storing the measurement result of the data retention times of the plurality of memory cells.

3. The operating method of claim 1, wherein the measuring of the data retention times comprises:
writing test data to the plurality of memory cells;
skipping a refresh operation on one or more test cells among the plurality of memory cells by a preset number of times; and
detecting the data retention times of the test cells by comparing the test data to data of the test cells.

4. The operating method of claim 1, wherein the measuring of the data retention times comprises:
a first detection step of detecting a cell group of which the data retention time is less than a reference time, among two or more cell groups, wherein the cell group comprises memory cells included in two or more rows, among the plurality of memory cells; and
a second detection step of detecting a sub cell group of which the data retention time is less than the reference time, among two or more sub cell groups included in the cell group detected at the first detection step, wherein the sub cell group comprises memory cells included in one or more rows of the two or more rows included in the cell group detected at the first detection step.

5. The operating method of claim 2, wherein the storing of the measurement result comprises:
storing the measurement result in a nonvolatile memory, a plurality of dummy cells, a plurality of latches or a plurality of fuses.

6. The operating method of claim 5, wherein the optimizing of the refresh operation comprises:
reading the measurement result stored in the nonvolatile memory, the plurality of dummy cells or the plurality of latches; and
adjusting a refresh cycle of the memory cell according to the measurement result.

7. The operating method of claim 1, wherein the optimizing of the refresh operation comprises:
detecting one or more weak cells having a shorter data retention time than a reference time, based on the measurement result, among the plurality of memory cells;
optimizing the refresh operation by increasing the data retention time of the weak cells or correcting data of the weak cells, and increasing a refresh cycle of the weak cell.

8. The operating method of claim 1, wherein the optimizing of the refresh operation comprises:
detecting one or more weak cells having a shorter data retention time than a first reference time, and detecting one or more strong cells having a longer data retention time than a second reference time, based on the measurement result, among the plurality of memory cells; and
minimizing a refresh frequency by decreasing a refresh cycle of the weak cells and increasing a refresh cycle of the strong cells.

9. The operating method of claim 1, wherein the measurement result includes an address of a weak cell or one-bit data indicating whether each memory cell is a weak cell.

10. A memory device comprising:
a plurality of memory cells;
a test control unit suitable for measuring data retention times of the plurality of memory cells; and
a refresh control unit suitable for controlling a refresh operation on the plurality of memory cells to be optimized, using the measurement result of the test control unit.

11. The memory device of claim 10, wherein the test control unit
writes test data to the plurality of memory cells, skips a refresh operation on one or more test cells among the plurality of memory cells by a preset number of times, and
detects the data retention times of the test cells by comparing the test data and data of the test cells.

12. The memory device of claim 10, wherein the test control unit
detects a cell group of which the data retention time is less than a reference time, among two or more cell groups, and
detects a sub cell group of which the data retention time is less that the reference time, among two or more sub cell groups included in the detected cell group,
wherein the cell group comprises memory cells included in two or more rows among the plurality of memory cells and the sub cell group comprises memory cells included in one or more rows of two or more rows included in the cell group.

13. The memory device of claim 10, further comprising a result storage unit suitable for storing the measurement result of the test control unit.

14. The memory device of claim 13, wherein the result storage unit comprising a nonvolatile memory, a plurality of dummy cell, a plurality of latches or a plurality of fuses.

15. The memory device of claim 13, wherein the refresh control unit adjusts a refresh cycle of the memory cell by referring to the measurement result stored in the result storage unit.

16. The memory device of claim 10, wherein the refresh control unit
detects one or more weak cells having a shorter data retention time than a reference time, based on the measurement result, among the plurality of memory cells, and
optimizes the refresh operation by increasing the data retention time of the weak cells or correcting data of the weak cells, and increasing a refresh cycle of the weak cell.

17. The memory device of claim 10, wherein the refresh control unit
detects one or more weak cells having a shorter data retention time than a first reference time, and detects one or more strong cells having a longer data retention time than a second reference time, based on the measurement result, among the plurality of memory cells, and
optimizes the refresh operation by decreasing a refresh cycle of the weak cells and increasing a refresh cycle of the strong cells.

18. The memory device of claim 10, further comprising:
a temperature measurement unit suitable for measuring a temperature at which the plurality of memory cells operate.

19. The memory device of claim 18, wherein the refresh control unit increases a refresh frequency as the temperature measured by the temperature measurement unit rises, and decreases the refresh frequency as the temperature measured by the temperature measurement unit falls.

20. The memory device of claim 10, wherein the measurement result includes an address of a weak cell or one-bit data indicating whether each memory cell is a weak cell.
